(19) United States
(12) Patent Application Publication
(10) Pub. No.: US 2025/0048847 A1
(43) Pub. Date: Feb. 6, 2025

(54) DISPLAY DEVICE AND MANUFACTURING METHOD THEREOF

(71) Applicant: Japan Display Inc., Tokyo (JP)

(72) Inventor: Sho YANAGISAWA, Tokyo (JP)

(73) Assignee: Japan Display Inc., Tokyo (JP)

(21) Appl. No.: 18/780,565

(22) Filed: Jul. 23, 2024

(30) Foreign Application Priority Data
Jul. 31, 2023 (JP) 2023-124535

(51) Int. Cl. H10K 59/122; H10K 59/12

(52) U.S. Cl. CPC H10K 59/122; H10K 59/1201

(57) ABSTRACT

According to one embodiment, a display device includes a first inorganic insulating layer, an organic insulating layer, a lower electrode, a second inorganic insulating layer provided on the organic insulating layer, an organic layer provided on the lower electrode, an upper electrode provided on the organic layer, and a plurality of terminals provided on the first inorganic insulating layer. The organic insulating layer has first apertures which overlap the terminals, respectively, and at least one second aperture located between the adjacent terminals. The second inorganic insulating layer has third apertures which overlap the terminals, respectively, and is in contact with the first inorganic insulating layer in the second aperture.

### CROSS-REFERENCE TO RELATED APPLICATION

This application is based upon and claims the benefit of priority from Japanese Patent Application No. 2023-124535, filed Jul. 31, 2023, the entire contents of which are incorporated herein by reference.

### FIELD

Embodiments described herein relate generally to a display device and a manufacturing method thereof.

### BACKGROUND

Recently, display devices to which an organic light emitting diode (OLED) is applied as a display element have been put into practical use. This display element comprises a pixel circuit including a thin-film transistor, a lower electrode connected to the pixel circuit, an organic layer which covers the lower electrode, and an upper electrode which covers the organic layer. The organic layer includes functional layers such as a hole transport layer and an electron transport layer in addition to a light emitting layer.

In the process of manufacturing such a display element, a technique which prevents the reduction in reliability has been required.

### BRIEF DESCRIPTION OF THE DRAWINGS

FIG. 1 is a diagram showing a configuration example of a display device DSP.

FIG. 2 is a diagram showing an example of the layout of subpixels SP1, SP2 and SP3.

FIG. 3 is a schematic cross-sectional view of the display device DSP along the A-B line of FIG. 2.

FIG. 4 is a plan view showing an example of a mother substrate 100 for a display device.

FIG. 5A is a plan view showing a configuration example of an area including terminals TE in the mother substrate 100 shown in FIG. 4.

FIG. 5B is a plan view showing a configuration example of an area including the terminals TE in the display device DSP shown in FIG. 1.

FIG. 6 is a cross-sectional view of the mother substrate 100 along the C-D line of FIG. 5A.

FIG. 7 is a cross-sectional view of the mother substrate 100 along the E-F line of FIG. 5A.

FIG. 8 is a cross-sectional view of the display device DSP along the G-H line of FIG. 5B.

FIG. 9 is a plan view showing another configuration example of an area including the terminals TE in the mother substrate 100 shown in FIG. 4.

FIG. 10 is a plan view showing another configuration example of an area including the terminals TE in the display device DSP shown in FIG. 1.

FIG. 11 is a diagram for explaining the manufacturing method of the display device DSP.

FIG. 12 is a diagram for explaining the manufacturing method of the display device DSP.

FIG. 13 is a diagram for explaining the manufacturing method of the display device DSP.

FIG. 14 is a diagram for explaining the manufacturing method of the display device DSP.

FIG. 15 is a diagram for explaining the manufacturing method of the display device DSP.

FIG. 16 is a diagram for explaining the manufacturing method of the display device DSP.

FIG. 17 is a diagram for explaining the manufacturing method of the display device DSP.

FIG. 18 is a diagram for explaining the manufacturing method of the display device DSP.

FIG. 19 is a diagram for explaining the manufacturing method of the display device DSP.

FIG. 20 is a cross-sectional view for explaining a state in which an evaporated film DF is formed in the terminal TE shown in FIG. 8.

FIG. 21 is a cross-sectional view for explaining a comparative example.

FIG. 22 is a cross-sectional view for explaining another comparative example.

### DETAILED DESCRIPTION

Embodiments described herein aim to provide a display device and a manufacturing method thereof such that the reduction in reliability can be prevented.

In general, according to one embodiment, a display device comprises a substrate, a first inorganic insulating layer provided over a display area which displays an image and a surrounding area located on an external side relative to the display area above the substrate, an organic insulating layer provided on the first inorganic insulating layer, a lower electrode provided on the organic insulating layer in the display area, a second inorganic insulating layer which is provided on the organic insulating layer and overlaps a peripheral portion of the lower electrode, an organic layer which is provided on the lower electrode and includes a light emitting layer, an upper electrode provided on the organic layer, and a plurality of terminals provided on the first inorganic insulating layer in the surrounding area. The organic insulating layer has first apertures which overlap the terminals, respectively, and at least one second aperture located between the adjacent terminals. The second inorganic insulating layer has third apertures which overlap the terminals, respectively, and is in contact with the first inorganic insulating layer in the second aperture.

According to another embodiment, a manufacturing method of a display device comprises forming a plurality of terminals on a first inorganic insulating layer in a surrounding area, forming an organic insulating layer which has first apertures overlapping the terminals, respectively, and at least one second aperture located between the adjacent terminals, forming a lower electrode on the organic insulating layer in a display area, forming a second inorganic insulating layer which has third apertures overlapping the terminals, respectively, is in contact with the first inorganic insulating layer in the second aperture, and overlaps a peripheral portion of the lower electrode, forming an organic layer including a light emitting layer on the lower electrode, and forming an upper electrode on the organic layer.

The embodiments can provide a display device and a manufacturing method thereof such that the reduction in reliability can be prevented.

Embodiments will be described with reference to the accompanying drawings.

The disclosure is merely an example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes, etc., of the respective parts are illustrated schematically in the drawings, rather than as an accurate representation of what is implemented. However, such schematic illustration is merely exemplary, and in no way restricts the interpretation of the invention. In addition, in the specification and drawings, structural elements which function in the same or a similar manner to those described in connection with preceding drawings are denoted by like reference numbers, detailed description thereof being omitted unless necessary.

In the drawings, in order to facilitate understanding, an X-axis, a Y-axis and a Z-axis orthogonal to each other are shown depending on the need. A direction parallel to the X-axis is referred to as a first direction X. A direction parallel to the Y-axis is referred to as a second direction Y. A direction parallel to the Z-axis is referred to as a third direction Z. When various elements are viewed parallel to the third direction Z, the appearance is defined as a plan view.

The display device of the present embodiment is an organic electroluminescent display device comprising an organic light emitting diode (OLED) as a display element, and could be mounted on a television, a personal computer, a vehicle-mounted device, a tablet, a smartphone, a mobile phone, etc.

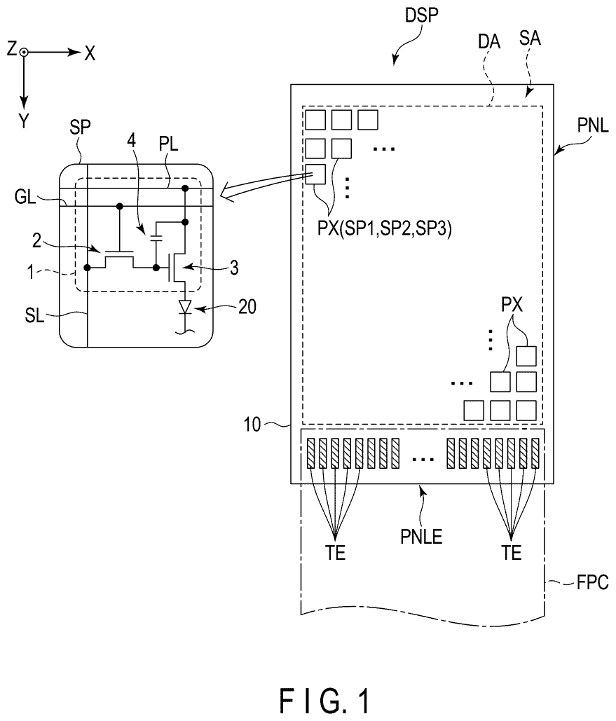

FIG. 1 is a diagram showing a configuration example of a display device DSP.

The display device DSP comprises a display panel PNL having a display area DA which displays an image and a surrounding area SA located on an external side relative to the display area DA on an insulating substrate 10. The substrate 10 may be glass or a resinous film having flexibility.

In the embodiment, the substrate 10 is rectangular as seen in plan view. It should be noted that the shape of the substrate 10 in plan view is not limited to a rectangle and may be another shape such as a square, a circle or an oval.

The display area DA comprises a plurality of pixels PX arrayed in matrix in a first direction X and a second direction Y. Each pixel PX includes a plurality of subpixels SP. For example, each pixel PX includes subpixel SP1 which exhibits a first color, subpixel SP2 which exhibits a second color and subpixel SP3 which exhibits a third color. The first color, the second color and the third color are different colors. Each pixel PX may include a subpixel SP which exhibits another color such as white in addition to subpixels SP1, SP2 and SP3 or instead of one of subpixels SP1, SP2 and SP3.

Each subpixel SP comprises a pixel circuit 1 and a display element 20 driven by the pixel circuit 1. The pixel circuit 1 comprises a pixel switch 2, a drive transistor 3 and a capacitor 4. Each of the pixel switch 2 and the drive transistor 3 is, for example, a switching element consisting of a thin-film transistor.

The gate electrode of the pixel switch 2 is connected to a scanning line GL. One of the source electrode and drain electrode of the pixel switch 2 is connected to a signal line SL. The other one is connected to the gate electrode of the drive transistor 3 and the capacitor 4. In the drive transistor 3, one of the source electrode and the drain electrode is connected to a power line PL and the capacitor 4, and the other one is connected to the anode of the display element 20.

It should be noted that the configuration of the pixel circuit 1 is not limited to the example shown in the figure. For example, the pixel circuit 1 may comprise more thin-film transistors and capacitors.

The display element 20 is an organic light emitting diode (OLED) as a light emitting element, and may be called an organic EL element.

The surrounding area SA comprises a plurality of terminals TE. The terminals TE are arranged unidirectionally along a panel end portion PNLE. In the example shown in the figure, the terminals TE are arranged in the first direction X. Each of the terminals TE extends in the second direction Y. However, the configuration is not limited to this example. For example, some of the terminals TE may extend in an oblique direction. For example, these terminals TE are electrically connected to a flexible printed circuit FPC shown by alternate long and short dash lines.

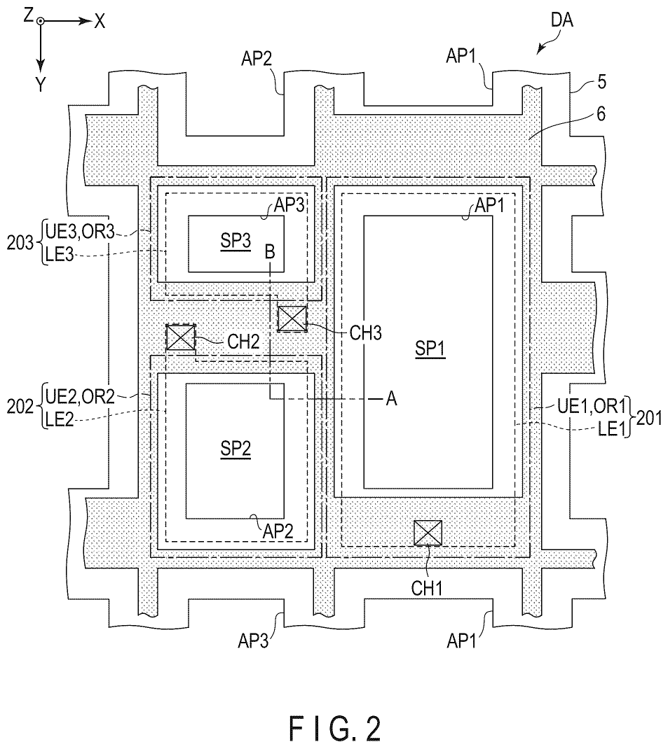

FIG. 2 is a diagram showing an example of the layout of subpixels SP1, SP2 and SP3.

In the example of FIG. 2, subpixels SP2 and SP3 are arranged in the second direction Y. Subpixels SP1 and SP2 are arranged in the first direction X, and subpixels SP1 and SP3 are arranged in the first direction X.

When subpixels SP1, SP2 and SP3 are provided in line with this layout, a column in which subpixels SP2 and SP3 are alternately provided in the second direction Y and a column in which a plurality of subpixels SP1 are provided in the second direction Y are formed in the display area DA. These columns are alternately arranged in the first direction X.

It should be noted that the layout of subpixels SP1, SP2 and SP3 is not limited to the example of FIG. 2. As another example, subpixels SP1, SP2 and SP3 in each pixel PX may be arranged in order in the first direction X.

An insulating layer 5 and a partition 6 are provided in the display area DA. The insulating layer 5 has apertures AP1, AP2 and AP3 in subpixels SP1, SP2 and SP3, respectively. The insulating layer 5 having these apertures AP1, AP2 and AP3 may be called a rib.

The partition 6 overlaps the insulating layer 5 as seen in plan view. The partition 6 is formed into a grating shape surrounding the apertures AP1, AP2 and AP3. In other words, the partition 6 has apertures in subpixels SP1, SP2 and SP3 in a manner similar to that of the insulating layer 5.

Subpixels SP1, SP2 and SP3 comprise display elements 201, 202 and 203, respectively, as the display elements 20.

The display element 201 of subpixel SP1 comprises a lower electrode LE1, an upper electrode UE1 and an organic layer OR1 overlapping the aperture AP1. The lower electrode LE1, the organic layer OR1 and the upper electrode UE1 are surrounded by the partition 6 as seen in plan view. The peripheral portion of each of the lower electrode LE1, the organic layer OR1 and the upper electrode UE1 overlaps the insulating layer 5 as seen in plan view.

The display element 202 of subpixel SP2 comprises a lower electrode LE2, an upper electrode UE2 and an organic layer OR2 overlapping the aperture AP2. The lower electrode LE2, the organic layer OR2 and the upper electrode UE2 are surrounded by the partition 6 as seen in plan view. The peripheral portion of each of the lower electrode LE2, the organic layer OR2 and the upper electrode UE2 overlaps the insulating layer 5 as seen in plan view.

The display element 203 of subpixel SP3 comprises a lower electrode LE3, an upper electrode UE3 and an organic layer OR3 overlapping the aperture AP3. The lower electrode LE3, the organic layer OR3 and the upper electrode UE3 are surrounded by the partition 6 as seen in plan view. The peripheral portion of each of the lower electrode LE3, the organic layer OR3 and the upper electrode UE3 overlaps the insulating layer 5 as seen in plan view.

In the example of FIG. 2, the outer shapes of the lower electrodes LE1, LE2 and LE3 are shown by dotted lines, and the outer shapes of the organic layers OR1, OR2 and OR3 and the upper electrodes UE1, UE2 and UE3 are shown by alternate long and short dash lines. It should be noted that the outer shape of each of the lower electrodes, organic layers and upper electrodes shown in the figure does not necessarily reflect the accurate shape.

The lower electrodes LE1, LE2 and LE3 correspond to, for example, the anodes of the display elements. The upper electrodes UE1, UE2 and UE3 correspond to the cathodes of the display elements or a common electrode.

The lower electrode LE1 is connected to the pixel circuit 1 (see FIG. 1) of subpixel SP1 through a contact hole CH1. The lower electrode LE2 is connected to the pixel circuit 1 of subpixel SP2 through a contact hole CH2. The lower electrode LE3 is connected to the pixel circuit 1 of subpixel SP3 through a contact hole CH3.

In the example of FIG. 2, the area of the aperture AP1, the area of the aperture AP2 and the area of the aperture AP3 are different from each other. The area of the aperture AP1 is greater than that of the aperture AP2, and the area of the aperture AP2 is greater than that of the aperture AP3. In other words, the area of the lower electrode LE1 exposed from the aperture AP1 is greater than that of the lower electrode LE2 exposed from the aperture AP2. The area of the lower electrode LE2 exposed from the aperture AP2 is greater than that of the lower electrode LE3 exposed from the aperture AP3.

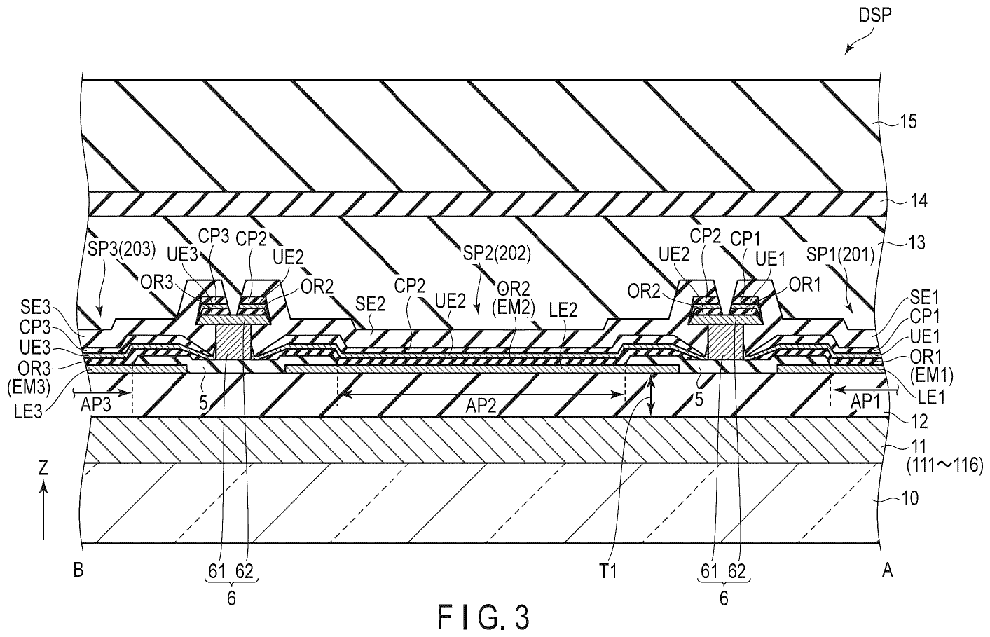

FIG. 3 is a schematic cross-sectional view of the display device DSP along the A-B line of FIG. 2.

A circuit layer 11 is provided on the substrate 10. The circuit layer 11 includes various circuits such as the pixel circuit 1 shown in FIG. 1 and various lines such as the scanning line GL, the signal line SL and the power line PL. The circuit layer 11 includes insulating layers 111, 112, 113, 114, 115 and 116 as described later. The circuit layer 11 is covered with an insulating layer 12. The insulating layer 12 is provided on the insulating layer 116 of the circuit layer 11 and is an organic insulating layer which planarizes the irregularities formed by the circuit layer 11. The insulating layer 12 has thickness T1.

The lower electrodes LE1, LE2 and LE3 are provided on the insulating layer 12 and are spaced apart from each other. The insulating layer 5 is an inorganic insulating layer and is provided on the insulating layer 12 and the lower electrodes LE1, LE2 and LE3. The aperture AP1 of the insulating layer 5 overlaps the lower electrode LE1. The aperture AP2 overlaps the lower electrode LE2. The aperture AP3 overlaps the lower electrode LE3. The peripheral portions of the lower electrodes LE1, LE2 and LE3 are covered with the insulating layer 5. The lower electrodes LE1, LE2 and LE3 are connected to the pixel circuits 1 of subpixels SP1, SP2 and SP3, respectively, through the contact holes provided in the insulating layer 12. It should be noted that, although the contact holes of the insulating layer 12 are omitted in FIG. 3, the contact holes correspond to the contact holes CH1, CH2 and CH3 of FIG. 2.

The partition 6 includes a conductive lower portion (stem) 61 provided on the insulating layer 5 and an upper portion (shade) 62 provided on the lower portion 61. The lower portion 61 of the partition 6 shown on the right side of the figure is located between the aperture AP1 and the aperture AP2. The lower portion 61 of the partition 6 shown on the left side of the figure is located between the aperture AP2 and the aperture AP3. The lower portion 61 may be either a single-layer body or a multilayer body. The upper portion 62 has a width greater than that of the lower portion 61. The both end portions of the upper portion 62 protrude relative to the side surfaces of the lower portion 61. This shape of the partition 6 is called an overhang shape.

The organic layer OR1 is in contact with the lower electrode LE1 through the aperture AP1 and covers the lower electrode LE1 exposed from the aperture AP1. The peripheral portion of the organic layer OR1 is located on the insulating layer 5. The upper electrode UE1 covers the organic layer OR1 and is in contact with the lower portion 61.

The organic layer OR2 is in contact with the lower electrode LE2 through the aperture AP2 and covers the lower electrode LE2 exposed from the aperture AP2. The peripheral portion of the organic layer OR2 is located on the insulating layer 5. The upper electrode UE2 covers the organic layer OR2 and is in contact with the lower portion 61.

The organic layer OR3 is in contact with the lower electrode LE3 through the aperture AP3 and covers the lower electrode LE3 exposed from the aperture AP3. The peripheral portion of the organic layer OR3 is located on the insulating layer 5. The upper electrode UE3 covers the organic layer OR3 and is in contact with the lower portion 61.

In the example of FIG. 3, subpixel SP1 comprises a cap layer CP1 and a sealing layer SE1. Subpixel SP2 comprises a cap layer CP2 and a sealing layer SE2. Subpixel SP3 comprises a cap layer CP3 and a sealing layer SE3. The cap layers CP1, CP2 and CP3 function as optical adjustment layers which improve the extraction efficiency of the light emitted from the organic layers OR1, OR2 and OR3, respectively.

The cap layer CP1 is provided on the upper electrode UE1.

The cap layer CP2 is provided on the upper electrode UE2.

The cap layer CP3 is provided on the upper electrode UE3.

The sealing layer SE1 is provided on the cap layer CP1, is in contact with the partition 6 and continuously covers the members of subpixel SP1.

The sealing layer SE2 is provided on the cap layer CP2, is in contact with the partition 6 and continuously covers the members of subpixel SP2.

The sealing layer SE3 is provided on the cap layer CP3, is in contact with the partition 6 and continuously covers the members of subpixel SP3.

In the example of FIG. 3, each of the organic layer OR1, the upper electrode UE1 and the cap layer CP1 is partly located on the partition 6 around subpixel SP1. These portions are spaced apart from, of the organic layer OR1, the upper electrode UE1 and the cap layer CP1, the portions located in the aperture AP1 (the portions constituting the display element 201).

Similarly, each of the organic layer OR2, the upper electrode UE2 and the cap layer CP2 is partly located on the partition 6 around subpixel SP2. These portions are spaced apart from, of the organic layer OR2, the upper electrode UE2 and the cap layer CP2, the portions located in the aperture AP2 (the portions constituting the display element 202).

Similarly, each of the organic layer OR3, the upper electrode UE3 and the cap layer CP3 is partly located on the partition 6 around subpixel SP3. These portions are spaced apart from, of the organic layer OR3, the upper electrode UE3 and the cap layer CP3, the portions located in the aperture AP3 (the portions constituting the display element 203).

The end portions of the sealing layers SE1, SE2 and SE3 are located above the partition 6. In the example of FIG. 3, the end portions of the sealing layers SE1 and SE2 located above the partition 6 between subpixels SP1 and SP2 are spaced apart from each other. The end portions of the sealing layers SE2 and SE3 located above the partition 6 between subpixels SP2 and SP3 are spaced apart from each other.

The sealing layers SE1, SE2 and SE3 are covered with a resin layer 13. The resin layer 13 is covered with a sealing layer 14. The sealing layer 14 is covered with a resin layer 15.

Each of the insulating layer 5, the sealing layers SE1, SE2 and SE3 and the sealing layer 14 is formed of, for example, an inorganic insulating material such as silicon nitride (SiNx), silicon oxide (SiOx), silicon oxynitride (SiON) or aluminum oxide (Al₂O₃).

The lower portion 61 of the partition 6 is formed of a conductive material and is electrically connected to the upper electrodes UE1, UE2 and UE3. The upper portion 62 of the partition 6 is formed of, for example, a conductive material. However, the upper portion 62 may be formed of an insulating material. The lower portion 61 is formed of a material which is different from that of the upper portion 62.

For example, each of the lower electrodes LE1, LE2 and LE3 is a multilayer body including a transparent electrode formed of an oxide conductive material such as indium tin oxide (ITO) and a metal electrode formed of a metal material such as silver.

The organic layer OR1 includes a light emitting layer EM1. The organic layer OR2 includes a light emitting layer EM2. The organic layer OR3 includes a light emitting layer EM3. The light emitting layer EM1, the light emitting layer EM2 and the light emitting layer EM3 are formed of materials which are different from each other. For example, the light emitting layer EM1 is formed of a material which emits light in a blue wavelength range. The light emitting layer EM2 is formed of a material which emits light in a green wavelength range. The light emitting layer EM3 is formed of a material which emits light in a red wavelength range.

Each of the organic layers OR1, OR2 and OR3 includes a plurality of functional layers such as a hole injection layer, a hole transport layer, an electron blocking layer, a hole blocking layer, an electron transport layer and an electron injection layer.

Each of the upper electrodes UE1, UE2 and UE3 is formed of, for example, a metal material such as an alloy of magnesium and silver (MgAg).

Each of the cap layers CP1, CP2 and CP3 is a multilayer body consisting of a plurality of thin films. All of the thin films are transparent and have refractive indices different from each other.

The circuit layer 11, insulating layer 12 and insulating layer 5 shown in FIG. 3 are provided over the display area DA and the surrounding area SA.

Now, this specification explains a mother substrate 100 for a display device for manufacturing a plurality of display devices DSP in a lump.

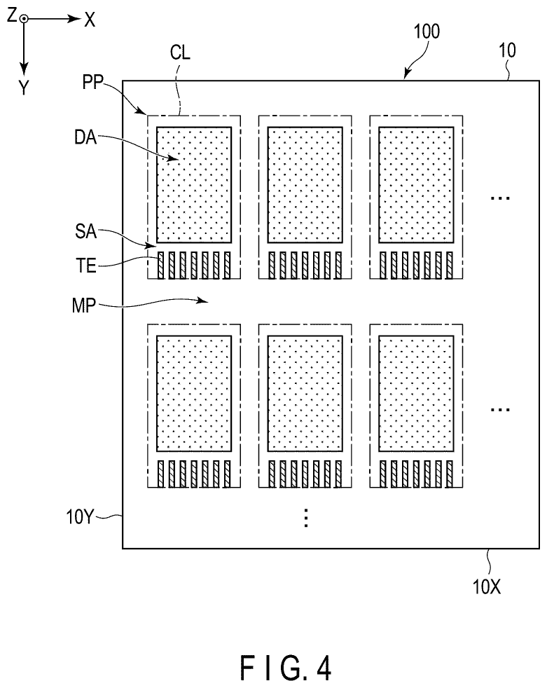

FIG. 4 is a plan view showing an example of the mother substrate 100.

The mother substrate 100 comprises a plurality of panel portions PP and a margin portion MP provided on an external side relative to these panel portions PP on a large substrate 10. The large substrate 10 is formed into, for example, a rectangular shape, and has a first side 10X extending in the first direction X and a second side 10Y extending in the second direction Y.

The panel portions PP are arrayed in matrix in the first direction X and the second direction Y. The panel portions PP are extracted by dividing the mother substrate 100 along cut lines CL. Each of the extracted panel portions PP corresponds to the display panel PNL shown in FIG. 1. Each panel portion PP comprises a display area DA and a surrounding area SA in which terminals TE and the like are provided.

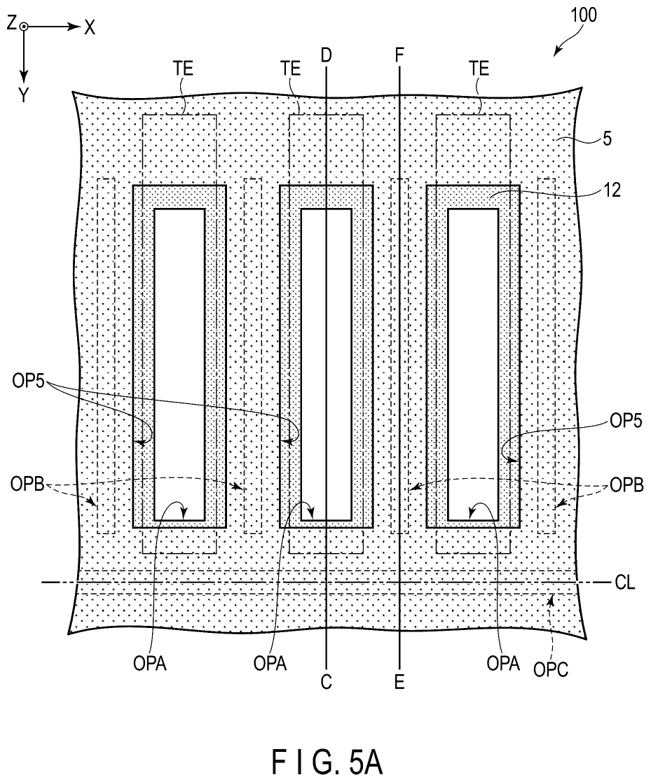

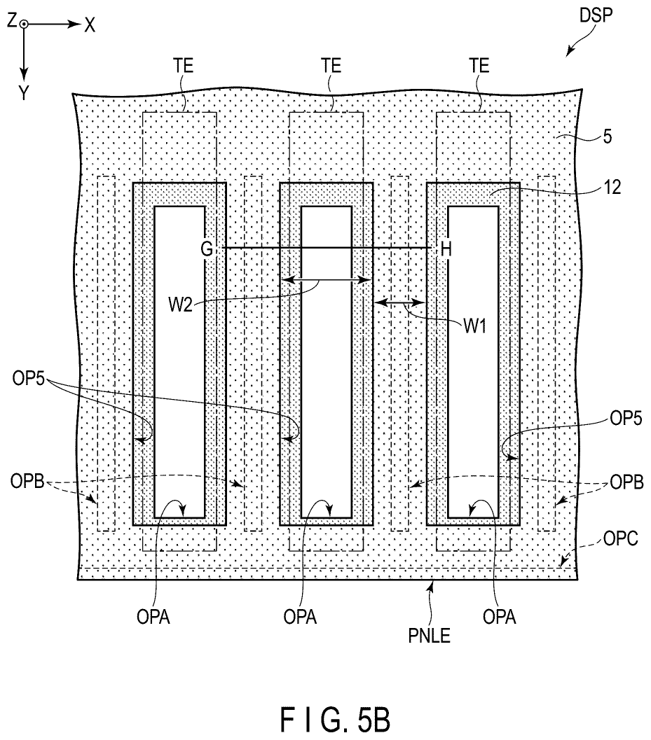

FIG. 5A is a plan view showing a configuration example of an area including the terminals TE in the mother substrate 100 shown in FIG. 4.

FIG. 5B is a plan view showing a configuration example of an area including the terminals TE in the display device DSP shown in FIG. 1. The display device DSP shown in FIG. 5B is obtained by dividing the mother substrate 100 shown in FIG. 5A along the cut line CL.

The terminals TE are arranged in the first direction X and extend in the second direction Y as shown by alternate long and short dash lines. As described above, the insulating layer 5 and the insulating layer 12 extend to an area including the terminals TE.

The insulating layer 12 has apertures OPA overlapping the terminals TE, respectively, an aperture OPB located between adjacent terminals, and an aperture OPC overlapping the cut line CL. The position of the cut line CL shown in FIG. 5A corresponds to the position of the panel end portion PNLE shown in FIG. 1 and FIG. 5B when the mother substrate 100 is divided.

In the examples shown in FIG. 5A and FIG. 5B, the apertures OPA overlap the terminals TE, respectively. Each aperture OPB is located between corresponding adjacent two terminals TE. These apertures OPA and OPB extend in a direction different from the first direction X corresponding to the direction in which the terminals TE are arranged. In the example shown in the figure, the apertures OPA and OPB extend in the second direction Y which is an example of a direction intersecting with the first direction X.

The aperture OPC overlaps the cut line CL parallel to the first direction X and extends in the first direction X. The apertures OPA, the apertures OPB and the aperture OPC are spaced apart from each other.

As shown in FIG. 5B, the insulating layer 5 has apertures OP5 overlapping the apertures OPA or the terminals TE, respectively. The area of each aperture OP5 is greater than that of each aperture OPA as seen in plan view. The edge of each aperture OP5 is located on an external side relative to the edge of a corresponding aperture OPA and does not intersect with the edge of a corresponding aperture OPA. The insulating layer 12 is exposed from the insulating layer 5 in each aperture OP5. Regarding the width parallel to the first direction X, width W1 of the insulating layer 5 between adjacent apertures OP5 is less than width W2 of each aperture OP5.

The insulating layer 5 overlaps the apertures OPB and the aperture OPC as seen in plan view.

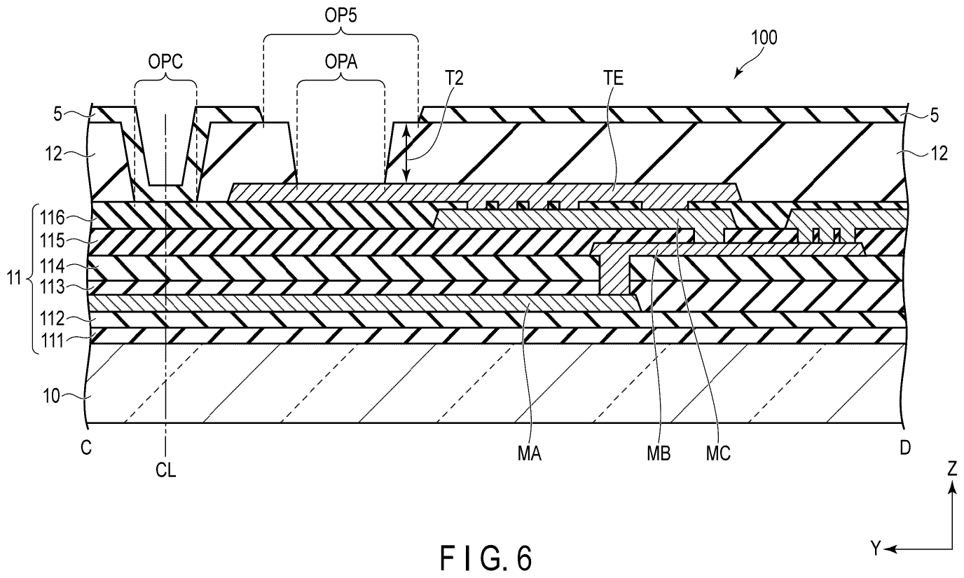

FIG. 6 is a cross-sectional view of the mother substrate 100 along the C-D line of FIG. 5A.

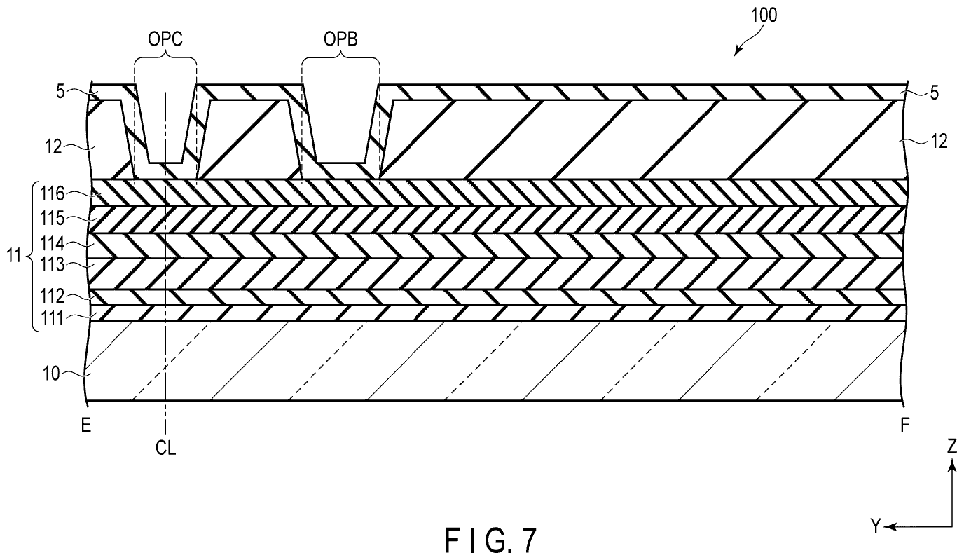

FIG. 7 is a cross-sectional view of the mother substrate 100 along the E-F line of FIG. 5A.

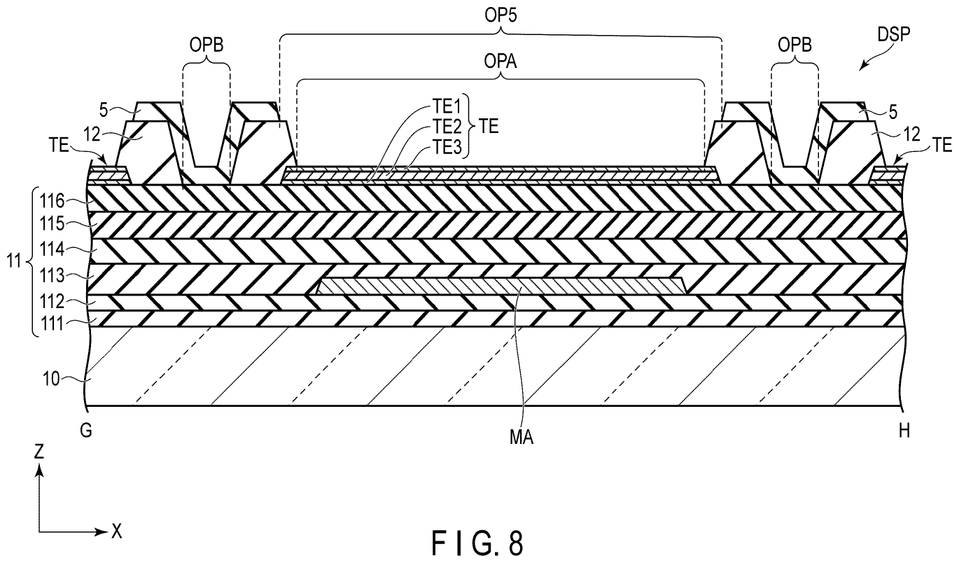

FIG. 8 is a cross-sectional view of the display device DSP along the G-H line of FIG. 5B.

The circuit layer 11 provided on the substrate 10 includes the insulating layers 111, 112, 113, 114, 115 and 116 and metal layers MA, MB and MC.

The insulating layer 111 is an inorganic insulating layer and is provided on the substrate 10. The insulating layer 112 is an inorganic insulating layer and is provided on the insulating layer 111. The metal layer MA is provided on the insulating layer 112. The insulating layer 113 is an inorganic insulating layer and is provided on the insulating layer 112 and the metal layer MA. The insulating layer 114 is an inorganic insulating layer and is provided on the insulating layer 113.

The metal layer MB is provided on the insulating layer 114 and is electrically connected to the metal layer MA. The insulating layer 115 is an inorganic insulating layer and is provided on the insulating layer 114 and the metal layer MB. The metal layer MC is provided on the insulating layer 115 and is electrically connected to the metal layer MB. The insulating layer 116 is an inorganic insulating layer and is provided on the insulating layer 115 and the metal layer MC.

The terminal TE is located immediately above the metal layer MA, is provided on the insulating layer 116 and is electrically connected to the metal layer MC.

The insulating layer 12 is provided on the insulating layer 116 and the terminal TE. The terminal TE is exposed from the insulating layer 12 in the aperture OPA. The peripheral portion of the terminal TE is covered with the insulating layer 12 over the whole circumference. The insulating layer 116 is exposed from the insulating layer 12 in the aperture OPB and the aperture OPC.

The terminal TE is electrically connected to the flexible printed circuit via an anisotropic conductive film. At this time, to prevent poor connection between the terminal TE and the flexible printed circuit, a step formed between the terminal TE and the insulating layer 12 around the terminal TE should be preferably small. For this reason, thickness T2 of the insulating layer 12 immediately above the terminal TE is less than thickness T1 of the insulating layer 12 for planarization immediately under the lower electrode LE2 shown in FIG. 3.

The insulating layer 5 is provided on the insulating layer 12 and is in contact with the insulating layer 116 which is an underlayer in the aperture OPB and the aperture OPC. In the example shown in the figures, the insulating layer 116 is covered with the insulating layer 5 in the aperture OPB and the aperture OPC. In this manner, both the insulating layer 5 and the insulating layer 116 are inorganic insulating layers, are in contact with each other and are attached firmly to each other. Thus, compared to a case where the insulating layer 5 which is an inorganic insulating layer is in contact with only the insulating layer 12 which is an organic insulating layer, the adherence between the insulating layer 5 and the underlayer is improved, thereby preventing the separation of the insulating layer 5.

Near the aperture OPA, the insulating layer 5 is provided on the upper surface of the insulating layer 12 and is not provided on the slope of the insulating layer 12 surrounding the aperture OPA. Thus, a path through which the moisture (or vapor) contained in the insulating layer 12 could be released can be formed in an area exposed from the insulating layer 5 in the insulating layer 12.

The insulating layer 5 is not in contact with the terminal TE. Thus, compared to a case where the insulating layer 5 is in contact with the terminal TE, the area of the region in which the terminal TE is exposed from the insulating layer 5 (or the area of the region in which the flexible printed circuit is connected to the terminal TE) can be increased.

Each of the insulating layers 111 to 116 is formed of one of silicon oxide, silicon nitride and silicon oxynitride. For example, each of the insulating layers 111, 114 and 116 is formed of silicon nitride, and each of the insulating layers 112, 113 and 115 is formed of silicon oxide. The insulating layer 5 is formed of, for example, silicon oxynitride.

As shown in FIG. 8, the terminal TE has a first conductive layer TE1, a second conductive layer TE2 and a third conductive layer TE3. The first conductive layer TE1 is provided on the insulating layer 116. The second conductive layer TE2 is provided on the first conductive layer TE1. The third conductive layer TE3 is provided on the second conductive layer TE2.

The first conductive layer TE1 and the third conductive layer TE3 are formed of, for example, the same material. The second conductive layer TE2 is formed of a material different from that of the first conductive layer TE1. For example, the second conductive layer TE2 is an aluminum layer formed of an aluminum-based material. Each of the first conductive layer TE1 and the third conductive layer TE3 is a titanium layer formed of a titanium-based material. It should be noted that each of the first conductive layer TE1 and the third conductive layer TE3 may be formed of a molybdenum-based material.

The insulating layer 12 covers the peripheral portion of the terminal TE. In other words, the side surfaces of the first conductive layer TE1, the second conductive layer TE2 and the third conductive layer TE3 are covered with the insulating layer 12. This configuration can prevent undesired corrosion of an aluminum layer caused by an etchant used in the process of forming the lower electrodes on the insulating layer 12.

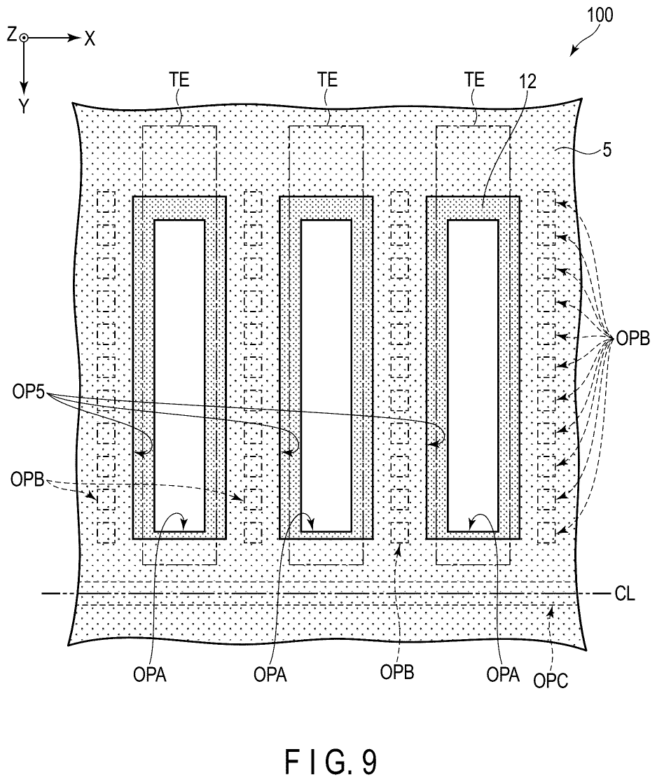

FIG. 9 is a plan view showing another configuration example of an area including the terminals TE in the mother substrate 100 shown in FIG. 4.

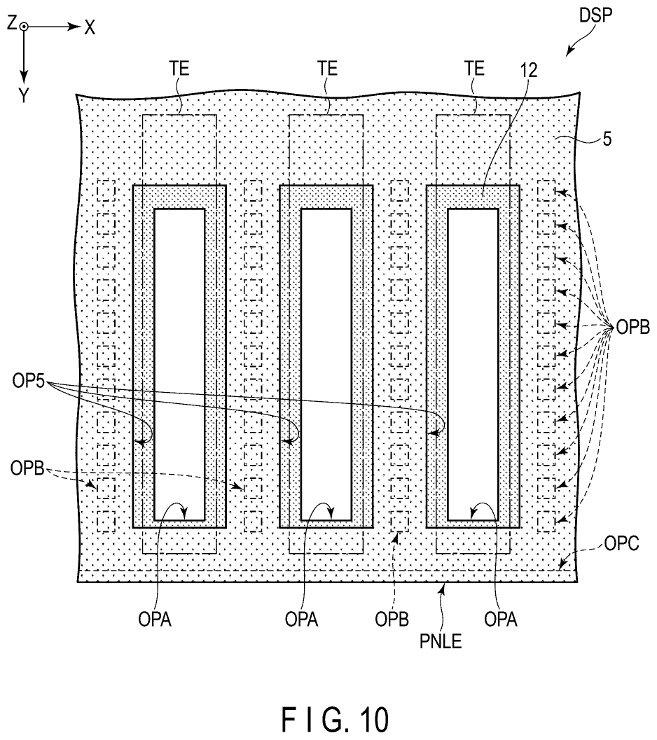

FIG. 10 is a plan view showing a configuration example of an area including the terminals TE in the display device DSP shown in FIG. 1. The display device DSP shown in FIG. 10 is obtained by dividing the mother substrate 100 shown in FIG. 9 along the cut line CL.

The configuration examples shown in FIG. 9 and FIG. 10 are different from those shown in FIG. 5A and FIG. 5B in respect that a plurality of apertures OPB are arranged between adjacent two terminals TE.

In the examples shown in FIG. 9 and FIG. 10, the apertures OPB are arranged in line in the second direction Y between adjacent two terminals TE. It should be noted that a plurality of apertures OPB may be arrayed in matrix in the first direction X and the second direction Y between adjacent two terminals TE.

The insulating layer 5 overlaps the apertures OPB and is in contact with the insulating layer 116 in each aperture OPB as shown in the cross-sectional view of FIG. 8 etc.

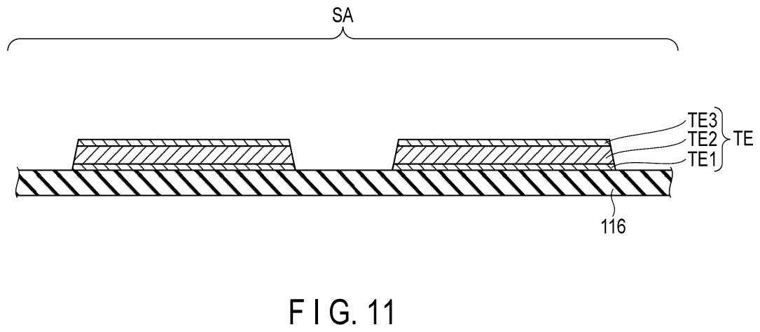

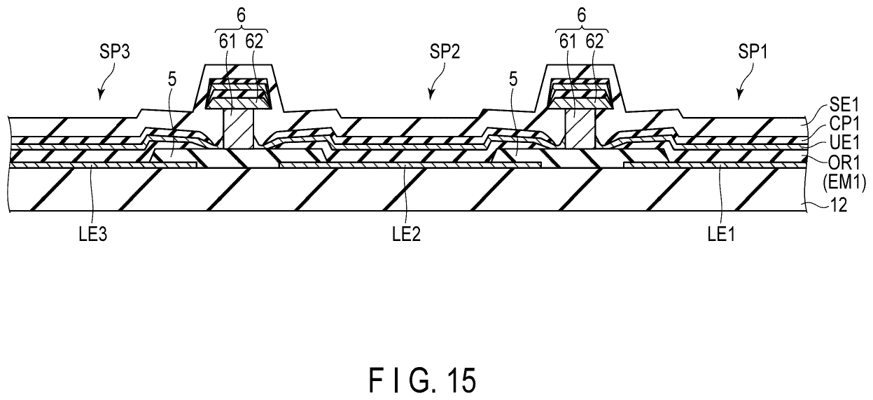

Now, this specification explains the manufacturing method of the display device DSP. Regarding FIG. 11 to FIG. 14, the illustration of the lower side than the insulating layer 116 is omitted. Regarding FIG. 15 to FIG. 19, the illustration of the lower side than the insulating layer 12 is omitted.

First, as shown in FIG. 11, a plurality of terminals TE are formed on the insulating layer 116 in the surrounding area SA. The process of forming the terminals TE includes the following steps. Specifically, the first conductive layer TE1 is formed on the insulating layer 116. The second conductive layer TE2 is formed on the first conductive layer TE1. The third conductive layer TE3 is formed on the second conductive layer TE2. Subsequently, the first conductive layer TE1, the second conductive layer TE2 and the third conductive layer TE3 are patterned. By this process, the terminals TE are formed.

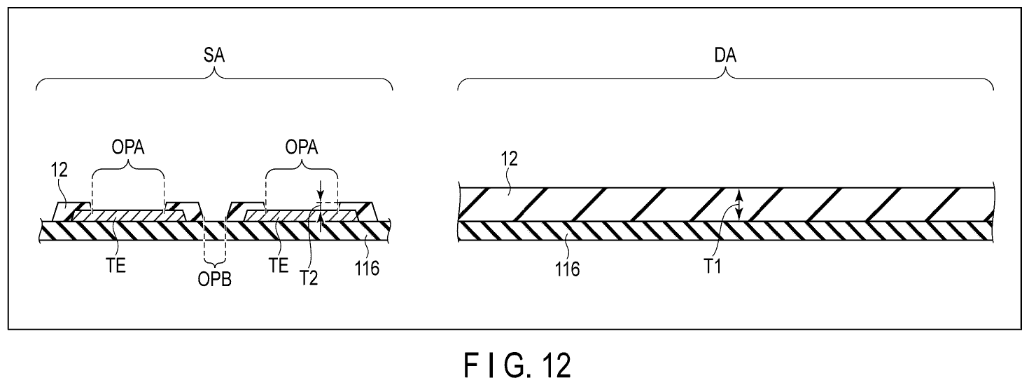

Subsequently, as shown in FIG. 12, the insulating layer 12 is formed over the display area DA and the surrounding area SA. The insulating layer 12 having thickness T1 is formed in the display area DA. The insulating layer 12 which covers the peripheral portion of each terminal TE and has thickness T2 which is less than thickness T1 immediately above each terminal TE is formed in the surrounding area SA. At this time, in the insulating layer 12, the aperture OPA which overlaps each terminal TE is formed, and further, the aperture OPB located between adjacent terminals is formed. In addition, although not shown in the figure, the aperture OPC which overlaps the cut line is formed in the insulating layer 12.

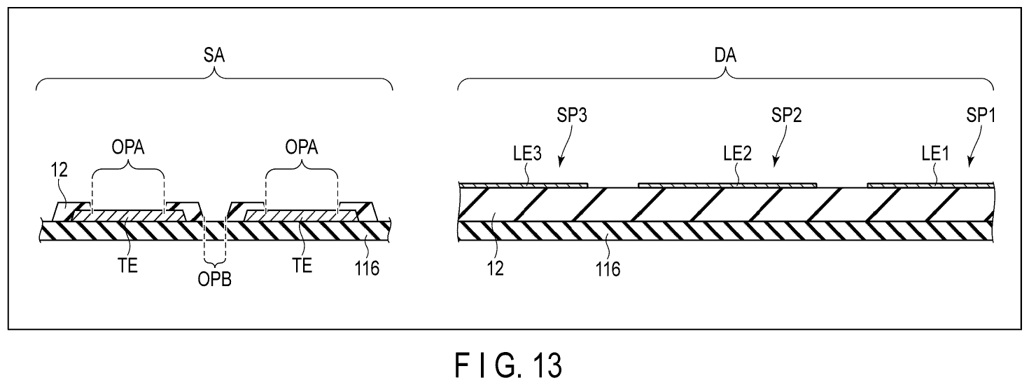

Subsequently, as shown in FIG. 13, the lower electrode LE1 of subpixel SP1, the lower electrode LE2 of subpixel SP2 and the lower electrode LE3 of subpixel SP3 are formed on the insulating layer 12 in the display area DA. The process of forming the lower electrodes LE1, LE2 and LE3 includes the following steps. An ITO layer is formed on the insulating layer 12. A silver layer is formed on the ITO layer. An ITO layer is formed on the silver layer. Subsequently, each of the ITO layer, the silver layer and the ITO layer is patterned by wet etching. By this process, the lower electrodes LE1, LE2 and LE3 are formed. At this time, as the peripheral portion of each terminal TE is covered with the insulating layer 12, the aluminum layer of each terminal TE can be protected.

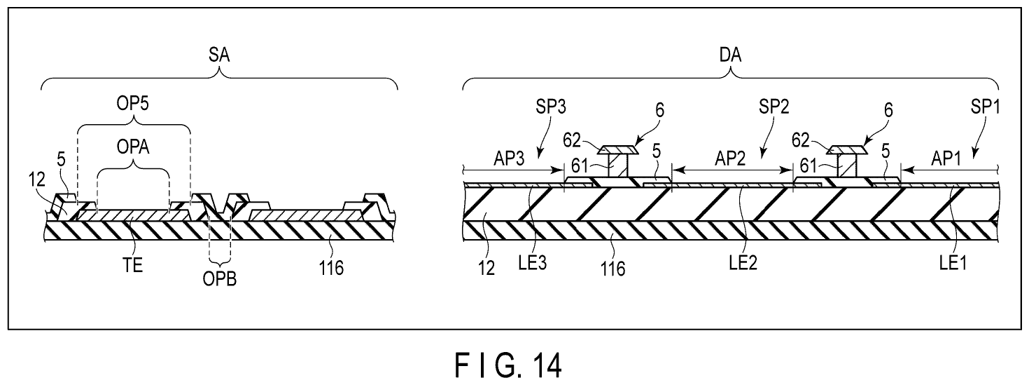

Subsequently, as shown in FIG. 14, the insulating layer 5 is formed over the display area DA and the surrounding area SA. At this time, the insulating layer 5 is in contact with the insulating layer 116 in each aperture OPB. In addition, although not shown in the figure, the insulating layer 5 is in contact with the insulating layer 116 in the aperture OPC.

Subsequently, in the display area DA, the partition 6 which comprises the lower portion 61 located on the insulating layer 5 and the upper portion 62 located on the lower portion 61 is formed.

Subsequently, the apertures AP1, AP2 and AP3 are formed in the insulating layer 5 of the display area DA, and the apertures OP5 are formed in the insulating layer 5 of the surrounding area SA. The aperture AP1 overlaps the lower electrode LE1 of subpixel SP1. The aperture AP2 overlaps the lower electrode LE2 of subpixel SP2. The aperture AP3 overlaps the lower electrode LE3 of subpixel SP3. The apertures OP5 are formed such that they overlap the terminals TE and the insulating layer 12 is exposed from the apertures OP5.

It should be noted that the formation process of the apertures AP1, AP2 and AP3 may be performed before the formation process of the partition 6.

Subsequently, the display element 201 is formed in the display area DA.

First, as shown in FIG. 15, the organic layer OR1 is formed by depositing the materials for forming the hole injection layer, the hole transport layer, the electron blocking layer, the light emitting layer EM1, the hole blocking layer, the electron transport layer, the electron injection layer, etc., on the lower electrode LE1 in series using the partition 6 as a mask.

Subsequently, the upper electrode UE1 is formed by depositing a mixture of magnesium and silver on the organic layer OR1 using the partition 6 as a mask. The upper electrode UE1 covers the organic layer OR1 and is in contact with the lower portion 61.

Subsequently, the cap layer CP1 is formed by depositing a high-refractive material and a low-refractive material in series on the upper electrode UE1 using the partition 6 as a mask.

These organic layer OR1, upper electrode UE1 and cap layer CP1 are continuously formed while maintaining a vacuum environment.

Subsequently, the sealing layer SE1 is formed so as to continuously cover the cap layer CP1 and the partition 6.

The organic layer OR1, the upper electrode UE1 and the cap layer CP1 are divided by the partition 6 having an overhang shape.

The materials which are emitted from an evaporation source when the organic layer OR1, the upper electrode UE1 and the cap layer CP1 are formed by vapor deposition are blocked by the upper portion 62. Thus, each of the organic layer OR1, the upper electrode UE1 and the cap layer CP1 is partly stacked on the upper portion 62. The organic layer OR1, upper electrode UE1 and cap layer CP1 located on the upper portion 62 are spaced apart from the organic layer OR1, upper electrode UE1 and cap layer CP1 located immediately above the lower electrode LE1.

These organic layer OR1, upper electrode UE1, cap layer CP1 and sealing layer SE1 are formed in the surrounding area SA and the margin portion MP in addition to the display area DA.

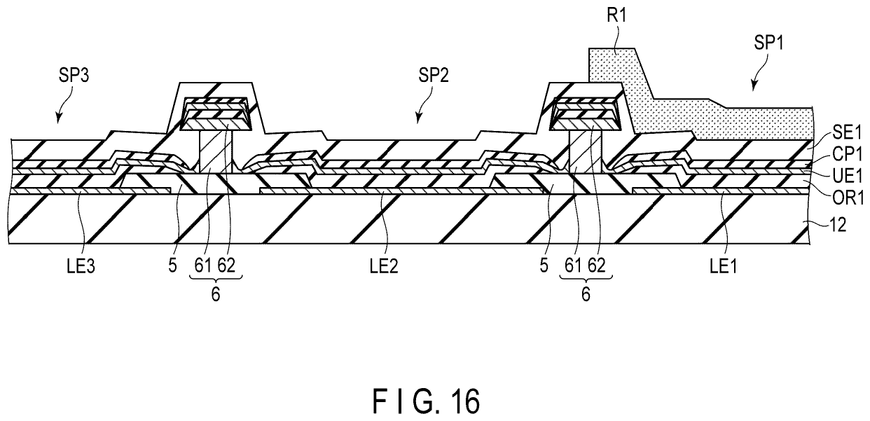

Subsequently, as shown in FIG. 16, a resist R1 patterned into a predetermined shape is formed on the sealing layer SE1. The resist R1 overlaps subpixel SP1 and part of the partition 6 around subpixel SP1.

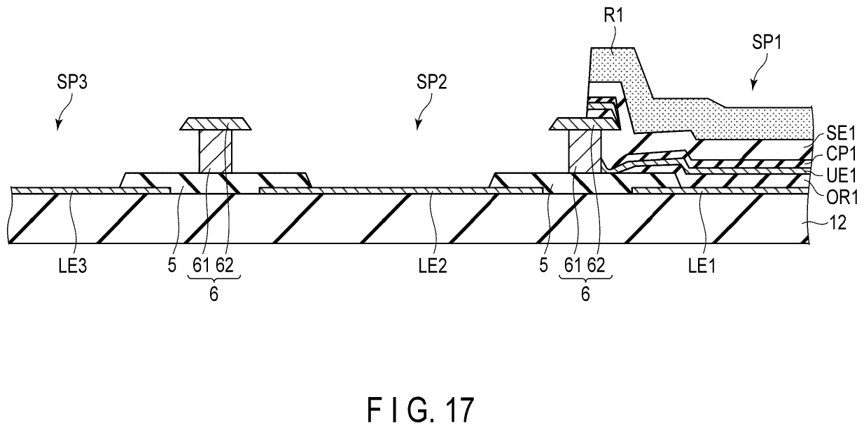

Subsequently, as shown in FIG. 17, the sealing layer SE1, cap layer CP1, upper electrode UE1 and organic layer OR1 exposed from the resist R1 are removed in series by performing etching using the resist R1 as a mask. In this manner, the lower electrode LE2 of subpixel SP2 and the lower electrode LE3 of subpixel SP3 are exposed.

Subsequently, the resist R1 is removed. By this process, the display element 201 is formed in subpixel SP1.

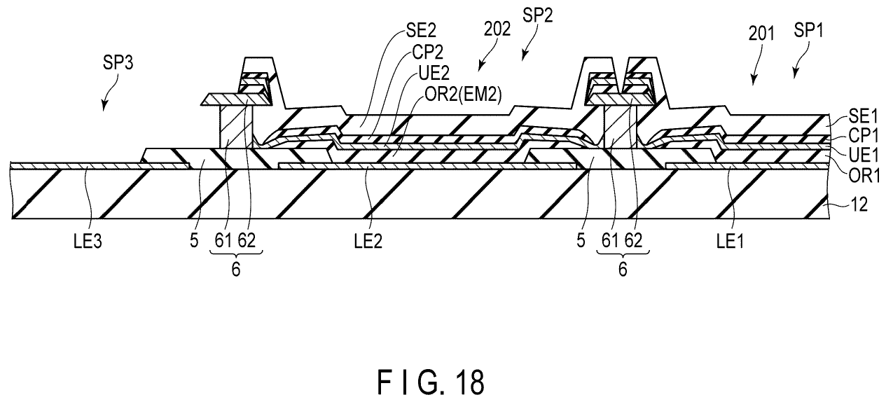

Subsequently, as shown in FIG. 18, the display element 202 is formed. The procedure of forming the display element 202 is similar to that of forming the display element 201. Specifically, the organic layer OR2 including the light emitting layer EM2, the upper electrode UE2, the cap layer CP2 and the sealing layer SE2 are formed in order on the lower electrode LE2. Subsequently, a resist is formed on the sealing layer SE2. The sealing layer SE2, the cap layer CP2, the upper electrode UE2 and the organic layer OR2 are patterned in series by etching using the resist as a mask. After this patterning, the resist is removed. In this manner, the display element 202 is formed in subpixel SP2, and the lower electrode LE3 of subpixel SP3 is exposed.

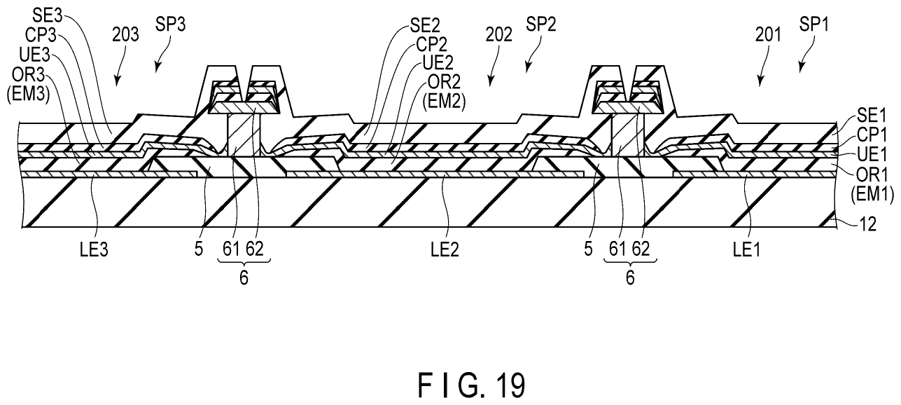

Subsequently, as shown in FIG. 19, the display element 203 is formed. The procedure of forming the display element 203 is similar to that of forming the display element 201. Specifically, the organic layer OR3 including the light emitting layer EM3, the upper electrode UE3, the cap layer CP3 and the sealing layer SE3 are formed in order on the lower electrode LE3. Subsequently, a resist is formed on the sealing layer SE3. The sealing layer SE3, the cap layer CP3, the upper electrode UE3 and the organic layer OR3 are patterned in series by etching using the resist as a mask. After this patterning, the resist is removed. By this process, the display element 203 is formed in subpixel SP3.

Subsequently, the resin layer 13, sealing layer 14 and resin layer 15 shown in FIG. 3 are formed in order. By this process, the display device DSP is completed.

In the manufacturing process described above, this specification assumes a case where the display element 201 is formed firstly, and the display element 202 is formed secondly, and the display element 203 is formed lastly. However, the formation order of the display elements 201, 202 and 203 is not limited to this example.

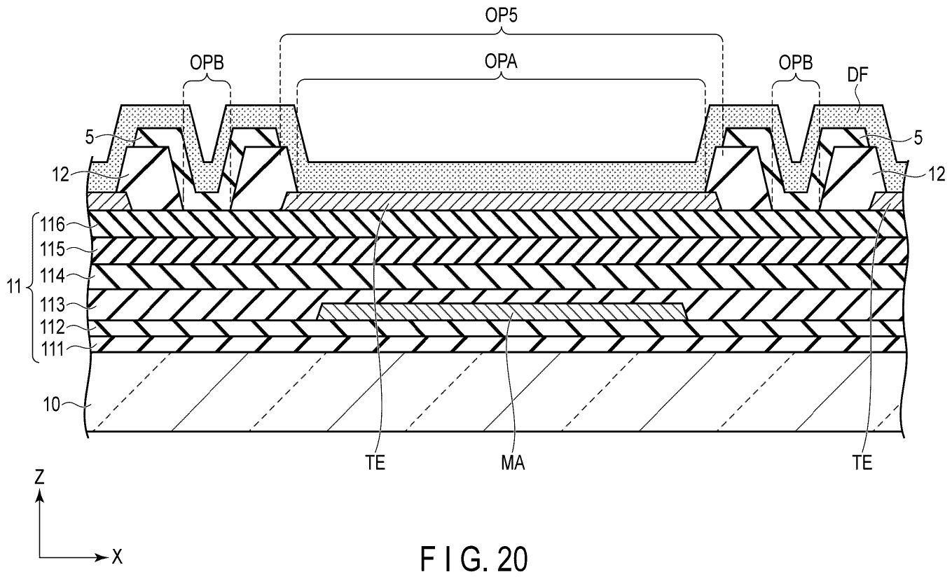

FIG. 20 is a cross-sectional view for explaining a state in which an evaporated film DF is formed in the terminal TE shown in FIG. 8.

In the process of forming each of the display elements 201, 202 and 203 described above, the evaporated film DF is formed in the surrounding area SA as well. Here, the evaporated film DF includes, for example, the organic layer OR1, upper electrode UE1 and cap layer CP1 for forming the display element 201 explained with reference to FIG. 15. The evaporated film DF is formed on the insulating layer 5, the insulating layer 12 and the terminal TE.

Since part of the insulating layer 12 is covered with the insulating layer 5, the damage caused to the insulating layer 12 in the manufacturing process prior to the formation of the display element 201 is reduced. In addition, compared to a case where the insulating layer 12 is not covered with the insulating layer 5, the contact area of the region which is affected by the damage in the insulating layer 12 and the evaporated film DF is small. The adherence between the evaporated film DF and the insulating layer 5 is firmer than the adherence between the evaporated film DF and the insulating layer 12. The contact area of the evaporated film DF and the insulating layer 5 is greater than the contact area of the evaporated film DF and the insulating layer 12. Thus, the separation of the evaporated film DF in the manufacturing process can be prevented.

Now, comparative examples are explained.

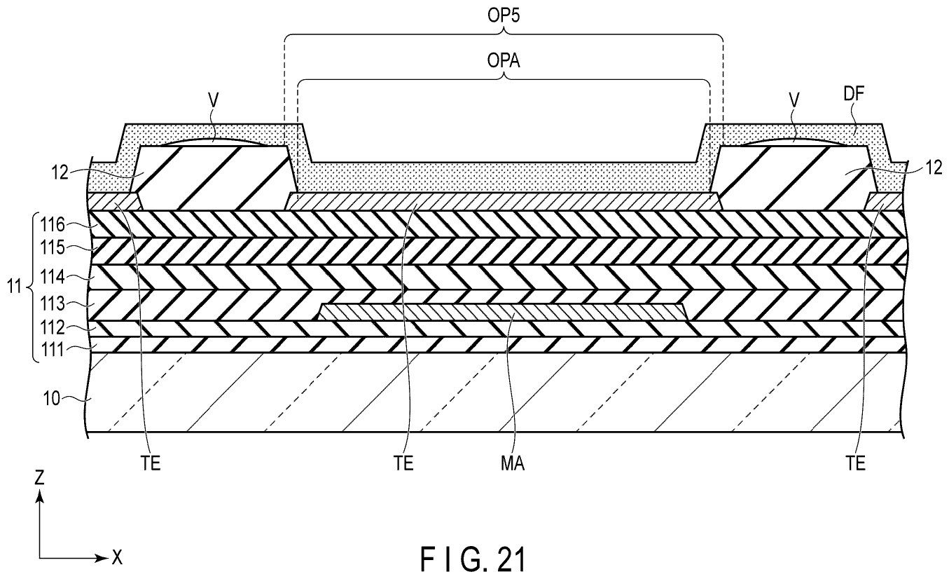

FIG. 21 is a cross-sectional view for explaining a comparative example.

In the comparative example shown in FIG. 21, the insulating layer 5 is not provided on the insulating layer 12. In this case, the surface of the insulating layer 12 easily becomes rough because of the damage to the insulating layer 12 in the manufacturing process prior to the formation of the display element 201. The evaporated film DF is formed on the insulating layer 12 and the terminal TE.

The adherence between these insulating layer 12 and evaporated film DF is weak, and thus, the evaporated film DF easily rises from the insulating layer 12. As shown in the figure, a void V may be formed between the insulating layer 12 and the evaporated film DF, and thus, the evaporated film DF may be even separated from the insulating layer 12.

Here, this specification explains problems which could occur when the evaporated film DF rises from the insulating layer 12 and is broken. The evaporated film DF separated from the insulating layer 12 floats inside the manufacturing equipment as a foreign substance and could be a contaminant source. If the floating foreign substance is attached to the processing substrate, various defects could be caused.

To the contrary, in the embodiment, the separation of the evaporated film DF can be prevented in an area including the terminals TE as explained with reference to FIG. 20. Moreover, the separation of the insulating layer 5 from the insulating layer 12 can be prevented as explained with reference to FIG. 8. This configuration prevents the contamination of the manufacturing equipment and the generation of undesired foreign substances. In this manner, the reduction in reliability is prevented.

Even in a case where the evaporated film DF includes the organic layer OR2, upper electrode UE2 and cap layer CP2 for forming the display element 202, similar effects are obtained.

In addition, even in a case where the evaporated film DF includes the organic layer OR3, upper electrode UE3 and cap layer CP3 for forming the display element 203, similar effects are obtained.

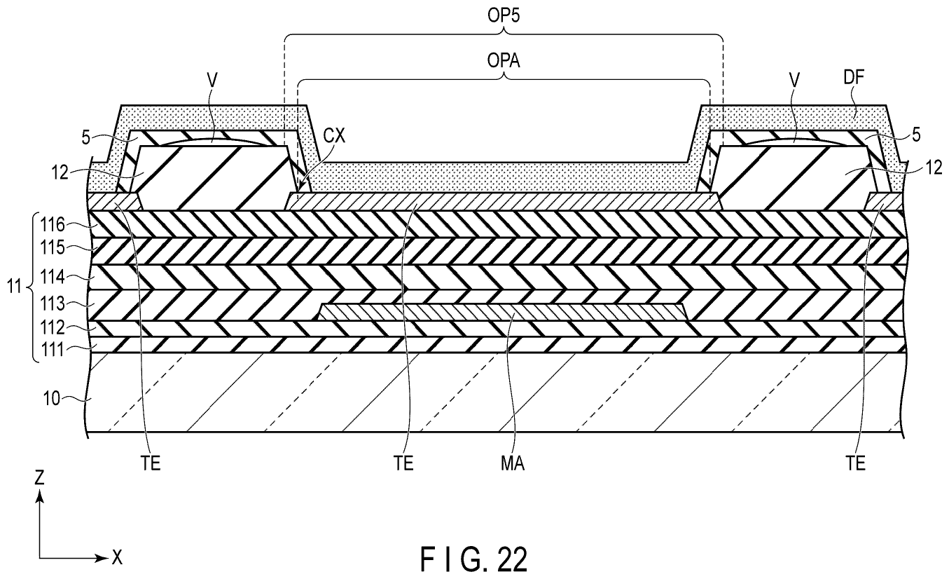

FIG. 22 is a cross-sectional view for explaining another comparative example.

In the comparative example shown in FIG. 22, the insulating layer 5 is formed so as to cover the insulating layer 12. The evaporated film DF is formed on the insulating layer 5 and the terminal TE.

In this case, a path through which the moisture (or vapor) contained in the insulating layer 12 could be released cannot be formed. Therefore, for example, as shown in the figure, a void V may be formed between the insulating layer 12 and the insulating layer 5 by the effect of the vapor released from the insulating layer 12, and thus, the insulating layer 5 may be separated from the insulating layer 12.

Further, a stress is easily concentrated in area CX where the insulating layer 12 which is an organic insulating layer, the insulating layer 5 which is an inorganic insulating layer and the terminal TE which is a metal layer are in contact with each other. When the evaporated film DF is formed in this area CX, the evaporated film DF easily rises from the insulating layer 5 based on area CX where a stress is concentrated, and thus, the evaporated film DF may be separated from the insulating layer 5.

In the embodiment, the separation of the insulating layer 5 from the insulating layer 12 and the separation of the evaporated film DF from the insulating layer 5 can be prevented as described above. In this manner, the reduction in reliability is prevented.

In the embodiment described above, for example, the insulating layer 116 corresponds to a first inorganic insulating layer. The insulating layer 5 corresponds to a second inorganic insulating layer. The insulating layer 12 corresponds to an organic insulating layer. Each aperture OPA corresponds to a first aperture. Each aperture OPB corresponds to a second aperture. Each aperture OP5 corresponds to a third aperture.

As explained above, the present embodiment can provide a display device and a manufacturing method thereof such that the reduction in reliability can be prevented.

All of the display devices and manufacturing methods thereof that can be implemented by a person of ordinary skill in the art through arbitrary design changes to the display device and manufacturing method thereof described above as the embodiments of the present invention come within the scope of the present invention as long as they are in keeping with the spirit of the present invention.

Various modification examples which may be conceived by a person of ordinary skill in the art in the scope of the idea of the present invention will also fall within the scope of the invention. For example, even if a person of ordinary skill in the art arbitrarily modifies the above embodiments by adding or deleting a structural element or changing the design of a structural element, or by adding or omitting a step or changing the condition of a step, all of the modifications fall within the scope of the present invention as long as they are in keeping with the spirit of the invention.

Further, other effects which may be obtained from the above embodiments and are self-explanatory from the descriptions of the specification or can be arbitrarily conceived by a person of ordinary skill in the art are considered as the effects of the present invention as a matter of course.

What is claimed is:

1. A display device comprising:
a substrate;
a first inorganic insulating layer provided over a display area which displays an image and a surrounding area located on an external side relative to the display area above the substrate;
an organic insulating layer provided on the first inorganic insulating layer;
a lower electrode provided on the organic insulating layer in the display area;
a second inorganic insulating layer which is provided on the organic insulating layer and overlaps a peripheral portion of the lower electrode;
an organic layer which is provided on the lower electrode and includes a light emitting layer;
an upper electrode provided on the organic layer; and
a plurality of terminals provided on the first inorganic insulating layer in the surrounding area, wherein
the organic insulating layer has first apertures which overlap the terminals, respectively, and at least one second aperture located between the adjacent terminals, and
the second inorganic insulating layer has third apertures which overlap the terminals, respectively, and is in contact with the first inorganic insulating layer in the second aperture.

2. The display device of claim 1, wherein
the second aperture extends in a direction intersecting with a direction in which the terminals are arranged.

3. The display device of claim 1, wherein
the second apertures are arranged in a direction intersecting with a direction in which the terminals are arranged.

4. The display device of claim 1, wherein
the organic insulating layer is exposed from the second inorganic insulating layer in each of the third apertures.

5. The display device of claim 1, wherein
in the organic insulating layer, a thickness immediately above each of the terminals is less than a thickness immediately under the lower electrode.

6. The display device of claim 1, wherein
each of the terminals is a multilayer body including an aluminum layer, and
the organic insulating layer covers a peripheral portion of each of the terminals.

7. The display device of claim 1, further comprising
a partition which has a lower portion provided on the second inorganic insulating layer and formed of a conductive material and an upper portion provided on the lower portion and protruding from a side surface of the lower portion in the display area,
the lower electrode, the organic layer and the upper electrode are surrounded by the partition in plan view, and
the upper electrode is in contact with the partition.

8. The display device of claim 1, wherein
each of the first inorganic insulating layer and the second inorganic insulating layer is formed of one of silicon oxide, silicon nitride and silicon oxynitride.

9. A manufacturing method of a display device, the method comprising:
forming a plurality of terminals on a first inorganic insulating layer in a surrounding area;
forming an organic insulating layer which has first apertures overlapping the terminals, respectively, and at least one second aperture located between the adjacent terminals;
forming a lower electrode on the organic insulating layer in a display area;
forming a second inorganic insulating layer which has third apertures overlapping the terminals, respectively, is in contact with the first inorganic insulating layer in the second aperture, and overlaps a peripheral portion of the lower electrode;
forming an organic layer including a light emitting layer, on the lower electrode; and
forming an upper electrode on the organic layer.

10. The manufacturing method of claim 9, wherein
each of the third apertures of the second inorganic insulating layer is formed such that the organic insulating layer is exposed from each of the third apertures.

11. The manufacturing method of claim 9, wherein
the organic insulating layer is formed such that a thickness immediately above each of the terminals is less than a thickness immediately under the lower electrode.

12. The manufacturing method of claim 9, wherein
the forming the plurality of terminals includes:
forming a first conductive layer on the first inorganic insulating layer;
forming a second conductive layer which is an aluminum layer on the first conductive layer;
forming a third conductive layer on the second conductive layer; and
patterning the first conductive layer, the second conductive layer and the third conductive layer.

13. The manufacturing method of claim 12, wherein
the organic insulating layer is formed so as to cover a peripheral portion of each of the terminals.

14. The manufacturing method of claim 9, wherein
further, before forming the organic layer,
in the display area, a partition which has a lower portion located on the second inorganic insulating layer and an upper portion located on the lower portion and protruding from a side surface of the lower portion is formed.

15. The manufacturing method of claim 14, wherein
each of the organic layer and the upper electrode is formed by vapor deposition using the partition as a mask.

16. The manufacturing method of claim 15, wherein
further, after forming the upper electrode,
a cap layer is formed on the upper electrode by performing vapor deposition using the partition as a mask, and
a sealing layer which covers the partition and the cap layer is formed.

17. The manufacturing method of claim 16, wherein
further, after forming the sealing layer,
a patterned resist is formed on the sealing layer, and
part of the sealing layer, part of the cap layer, part of the upper electrode and part of the organic layer are removed in series by performing etching using the resist as a mask.

18. The manufacturing method of claim 9, wherein
each of the first inorganic insulating layer and the second inorganic insulating layer is formed of one of silicon oxide, silicon nitride and silicon oxynitride.
